(19) United States
(12) Patent Application Publication
(10) Pub. No.: US 2024/0013836 A1
(43) Pub. Date: Jan. 11, 2024

(54) PREVENTION OF FLOATING GATE 3D-NAND CELL RESIDUAL BY USING HYBRID PLUG PROCESS IN SUPER-DECK STRUCTURE

(71) Applicant: Intel NDTM US LLC, Santa Clara, CA (US)

(72) Inventors: Chih Ting LIN, New Taipei City (TW); Jong Sun SEL, DALIAN (CN)

(21) Appl. No.: 18/237,077

(22) Filed: Aug. 23, 2023

(30) Foreign Application Priority Data
Jul. 28, 2023 (WO) PCT/CN2023/109871

(51) Int. Cl. G11C 16/04; H10B 41/27; H10B 41/35; H10B 43/27; H10B 43/35

(52) U.S. Cl. CPC G11C 16/0483; H10B 41/27; H10B 41/35; H10B 43/27; H10B 43/35

(57) ABSTRACT

Integration methods for prevention of floating gate 3D-NAND cell residual using a hybrid plug process in a super-deck structure and associated apparatus. A first desk layered structure comprising alternating isolation and conductor layers having a top isolation layer is formed over a substrate. A Silicon Nitride (SiN) layer is formed over the top isolation layer. An array of pillar holes vertically passing through the SiN layer and layers in the first deck layered structure are formed. The pillar holes are filled with a sacrificial film and an upper portion of the pillar holes are filled with a hybrid plug comprising first and second oxides. A second layered structure comprising alternating isolation and conductor layers having a bottom isolation layer is formed over the SiN layer, and an array of pillar holes are formed in the second deck layered structure. The hybrid plugs and sacrificial film is then removed using etching.

### RELATED APPLICATION

The present application claims the benefit of priority to Patent Cooperation Treaty (PCT) Application No. PCT/CN2023/109871, filed Jul. 28, 2023, the entire content of which is incorporated herein by reference.

### BACKGROUND INFORMATION

Three-dimensional (3D) NAND (not AND) technologies are commonly used to create nonvolatile (NV) storage devices, such as solid-state drives (SSDs). Reference to 3D NAND can more specifically refer to NAND flash. Unlike convention 2D memory devices, 3D NAND memory devices have one or more decks comprising tiers of circuit elements that are stacked on top of one another. The circuit elements are connected via channels in vertical structures (e.g., memory holes or pillars) having high depth to width aspect ratios (AR).

Some 3D NAND devices employ floating-gate memory cells (referred to FG cells). FG cells will have residual material at certain locations such as dummy wordline (WL) at transition area in 3D NAND because of the general process design. To fabricate the FG to cell, a pocket structure (i.e., a recess) is created in each cell so that the FG can be placed in this recess and separated from other cells. An inter-deck structure such as silicon nitride (SiN) requires a nitride-pull-back (NPB) process to open the pillar critical dimension (CD), then the pocket structure can be also created at this inter-deck corner location so the FG residual will be generated, which will induce some reliability issue at the dummy WL which is near the inter-deck residual location.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a block diagram of an example of a system that stores data in Non-volatile (NV) media;

FIG. 2 is a block diagram of an example of system including a three-dimensional (3D) memory device structure;

FIG. 3 is a diagram illustrating an abstracted representation of a portion of a solid-state memory component, according to one example;

FIG. 4 is a diagram illustrating a simplified structure of a memory cell implemented in the solid-state memory component of FIG. 3;

FIG. 5 is a diagram representing a cross-section view of a portion of a vertical channel in a 3D memory structure, according to one embodiment;

FIG. 6a-6i are diagrammatic representations of a cross-section of stages of processing of a 3D memory structure, according to one embodiment;

FIG. 7a-7h are diagrammatic representations of a cross-section of stages of processing of a 3D memory structure, according to one embodiment;

FIG. 8 is a flowchart illustrating processes for forming/fabricating semiconductor structures used in 3D NAND memory devices shown in FIGS. 6a-6i and 7a-7h;

FIG. 9 is a process flow diagram illustrating further details of selected processes implemented in forming a 3D memory structure in accordance with aspects of embodiments disclosed herein;

FIG. 10a is a cross-section diagram showing a reduction in oxide residual that results using the 3D memory fabrication processes described herein;

FIG. 10b is a model of the semiconductor structure fabrication process illustrating details of a pillar before and after a wet cleaning (etching operation);

FIG. 11 is a schematic diagram illustrating details of a hybrid plug in accordance with embodiments herein;

FIG. 12a is a block diagram of an example of a system with a hardware view of a solid-state drive (SSD) with a nonvolatile array having a vertical channel with conductive structures;

FIG. 12b is a block diagram of an example of a logical view of system with a solid-state drive (SSD) with a nonvolatile array having a vertical channel with conductive structures; and

FIG. 13 is a scanning electron microscope scan of a 3D NAND super-deck structure illustrating “hiding side” formation of oxide residual.

### DETAILED DESCRIPTION

Embodiments of integration methods for prevention of floating gate 3D-NAND cell residual using a hybrid plug process in a super-deck structure and associated apparatus are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

In accordance with aspects of the embodiments disclosed herein, a process integration method called hybrid plug is provided that utilizes an SiN inter-deck in a super-deck/supercell 3D memory structure. The integration method enabled elimination or reduction of cell residual oxide at the inter-deck location for floating-gate memory cell structures in memory devices employing the 3D memory structure, such as 3D NAND flash devices.

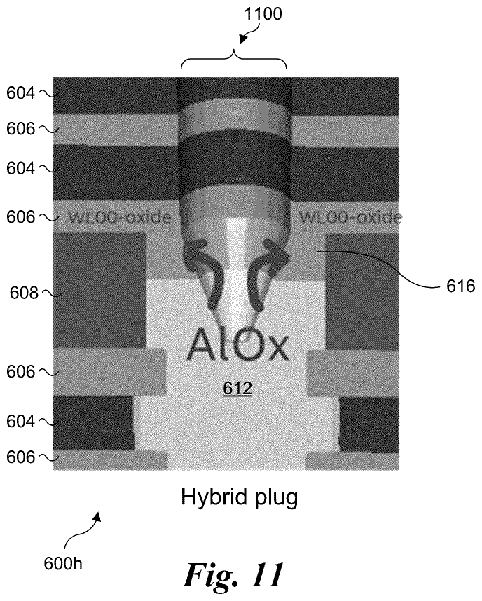

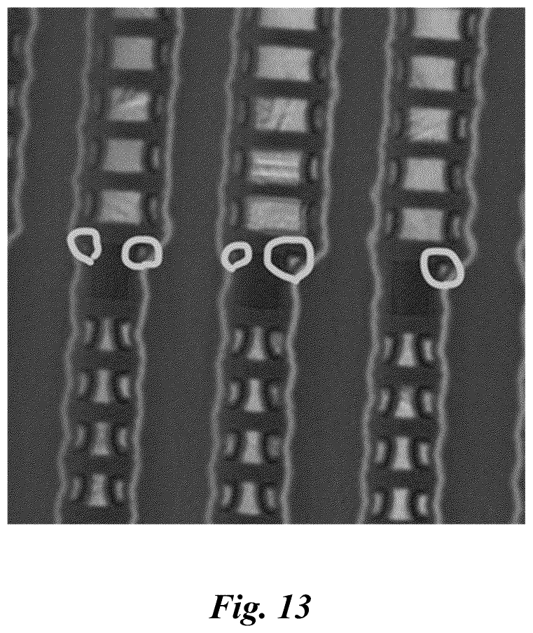

The integration method incorporates a SiN inter-deck with a hybrid plug process, creating a thin oxide on top of an AlOx plug. This oxide results in a smoother profile attached at the corner of SiN after pillar etching and the clean process, thus preventing the small “hiding-side” formation (see FIG. 13) then the cell residual can be eliminated or significantly reduced, as shown the schematic in FIG. 11 described and illustrated below. This fabrication process also prevents the AlOx plug back sputtering to the wordline 00 (WL00) oxide at top-sub-deck in this process flow. The AlOx back sputtering will result in WL00 CD shrinkage under a conventional fabrication method. In this improved process flow, because the AlOx plug location is further pulled down, the AlOx back-sputtering will not impact WL00-oxide.

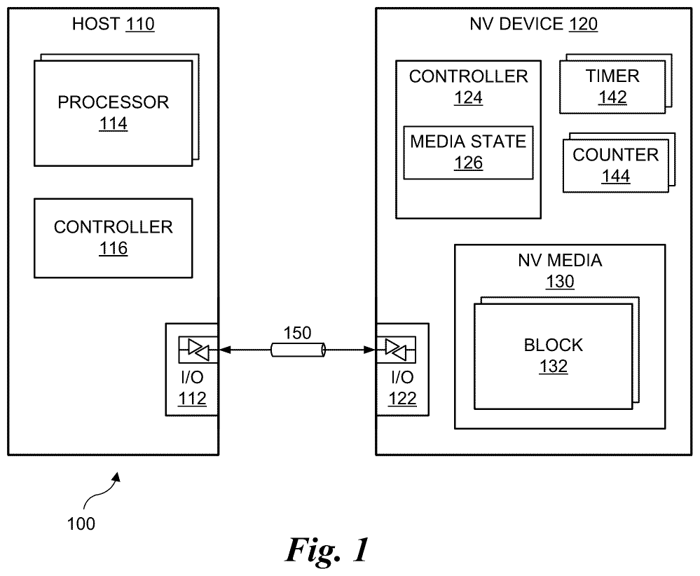

FIG. 1 is a block diagram of an example of a system that stores data in Non-volatile (NV) media. System 100 includes host 110 coupled to NV device 120. Host 110 represents a computing device. Host 110 includes I/O (input/output) 112, which represents hardware to interconnect with NV device 120. NV device 120 includes I/O 122 which corresponds to I/O 112. I/O 122 represents hardware to interconnect with host 110.

Host 110 provides a hardware platform to operate NV device 120. Host 110 includes one or more processors 114 to perform the operations of host 110. Processor 114 executes a host operating system (OS) that provides a software platform for the operation of NV device 120. The hardware platform provides hardware resources to interface with NV device 120 including transceiver hardware to perform access to the device. The software platform includes control software to execute other software elements such as applications or other agents that execute under the OS and create requests to access NV device 120.

I/O 112 and I/O 122 interconnect through one or more signal lines 150. Signal lines 150 typically include multiple separate lines and can be considered one or more buses to connect host 110 to NV device 120. Host 110 can send a host read command over signal line 150 to NV device 120. In response to the read command, NV device 120 services the request out of a transient Vt state, in accordance with any example provided.

In one example, host 110 includes controller 116. Controller 116 represents a memory controller or storage controller. In one example, controller 116 is integrated with processor 114. In one example, controller 116 is separate from processor 114. Controller 116 enables host 110 to manage access to NV device 120. In response to host operations by processor 114 that request access to data on NV device 120, controller 116 provides access to NV device 120. Controller 116 can represent hardware and firmware elements of host 110 to enable interaction with NV device 120.

NV device 120 includes controller 124, which represents a storage controller at the side of the storage device, which is separate from controller 116 of host 110. Controller 116 of host 110 represents components of the host system. Controller 124 represents components of the storage device or memory device into which the NV media is incorporated. Controller 124 receives commands sent from host 110 and determines how to service the command or request from the host. Controller 124 performs operations to access (e.g., read or write) NV media 130 in response to the host command.

NV media 130 represents a nonvolatile storage media of NV device 120. In one example, NV media 130 includes three-dimensional (3D) NAND (not AND) memory cells. In one example, NV media 130 includes 3D NOR memory cells. In one example, NV media 130 includes 3D crosspoint (XPOINT™) memory cells.

NV media 130 includes bitcells or memory cells organized as blocks 132. A block of memory refers to a portion of NV media 130 that is jointly charged or activated for an access operation. In one example, blocks 132 are subdivided as subblocks. In one example, a block refers to bitcells that share a select gate line. In one example, multiple subblocks share a select gate (e.g., a common select gate source (SGS) or a common select gate drain (SGD)) connector.

In one example, a block refers to an erase unit, or a unit size of NV media 130 that is erased together and monitored by controller 124 for number of writes. In one example, NV media 130 includes single level cell (SLC) and multilevel cell (MLC) media. For example, NV media 130 can include SLC and QLC (quad level cell) or SLC and TLC (triple level cell) bitcells. The block size could be different depending on the media type.

In one example, controller 124 is an ASIC (application specific integrated circuit) that controls operation of NV device 120. In one example, controller 124 is a CPU (central processing unit) core or processor device on NV device 120. In one example, NV device 120 represents an SSD and controller 124 controls multiple NV media dies or NV media chips integrated into the SSD. In one example, NV device 120 represents a module or PCB (printed circuit board) that includes multiple NV media dies or NV media chips integrated onto it and controller 124 controls the NV media dies of the module. In one example, controller 124 executes firmware to manage NV device 120. In one example, controller 124 executes firmware to manage NV device 120, including firmware to control the servicing of a read command based on whether the NV media is in thermal equilibrium.

In one example, controller 124 manages Vt state detection and read command servicing based on idle time or delay between consecutive read commands. In one example, controller 124 monitors one or more media states 126. Media state 126 represents a state of a portion of memory (such as a block) and can determine how to access the media based on media state 126. For example, if media state 126 indicates that a target block is in a stable state, controller 124 can first issue a dummy read prior to accessing the target block. In one example NV media devices 120 may include one or more timers 142 and counters 144.

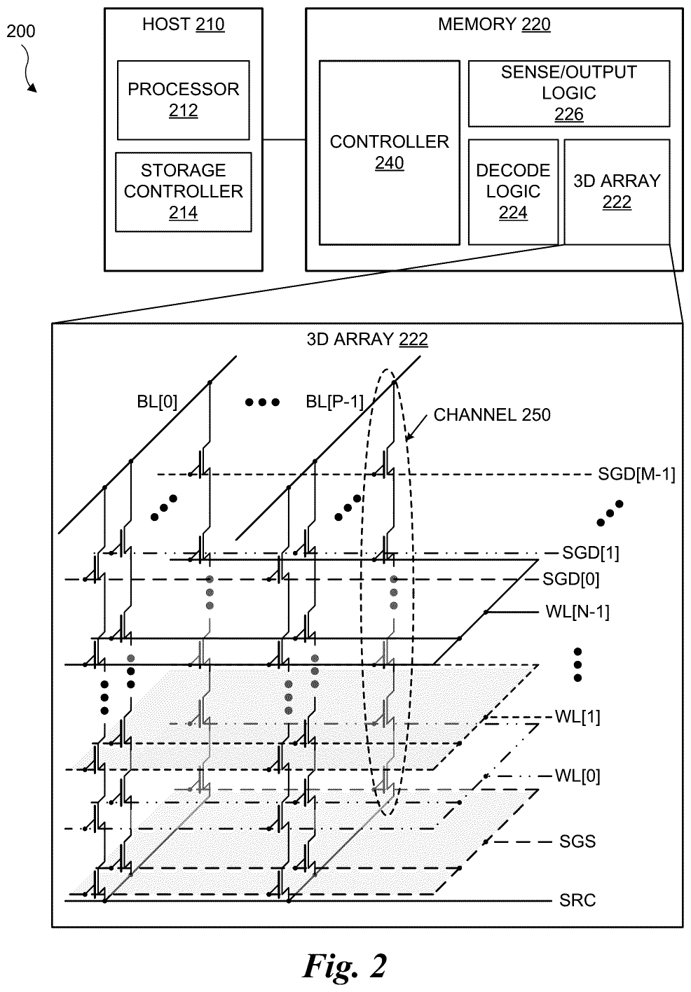

FIG. 2 is a block diagram of an example system illustrating further details of a 3D memory device structure. System 200 represents a computing device that includes a 3D memory. Host 210 represents a hardware platform that performs operations to control the functions of system 200. Host 210 includes processor 212, which is a host processor that executes the operations of the host. In one example, processor 212 is a single-core processor. In one example, processor 212 is a multicore processor device. Processor 212 can be a general-purpose processor that executes a host operating system or a software platform for system 200. In one example, processor 212 is an application specific processor, a graphics processor, a peripheral processor, or other controller or processing unit on host 210. Processor 212 executes multiple agents or software programs (not specifically shown). The agents can be standalone programs and/or threads, processes, software modules, or other code and data to be operated on by processor 212.

During execution of operations by processor 212, an agent executed by the processor can request data and/or code that is not stored at host 210 (e.g., in a cache or main memory), and therefore should be obtained from memory 220. Storage controller 214 generates and processes memory access commands to memory 220 to perform the memory access. Storage controller 214 represents a circuit or logic or processor that manages access to memory 220. In one example, storage controller 214 is part of host 210. In one example, storage controller 214 is part of processor 212. In one example, storage controller 214 is integrated on a common substrate with processor 212. In one example, storage controller 214 separate chip from processor 212, and can be integrated in a multichip package (MCP) with processor 212.

Memory 220 includes controller 240, which represents a controller at the memory or storage device to process and service commands from storage controller 214. In one example, controller 240 represents a controller for a memory device. In one example, controller 240 represents a controller for a memory module. Memory 220 includes 3D array 222. In one example, 3D array 222 includes NAND memory blocks. In one example, 3D array 222 includes QLC NAND memory blocks.

As illustrated, bitlines (BL) intersect the planes of the tiers of wordlines (WL). As an example, each wordline WL[0:(N-1)] is a tier. There can be P bitlines (BL[0:(P-1)]). In one example, 3D array 222 is also divided into subblocks through SGD[0:(M-1)], which divide each wordline into separate segments within a tier or within a plane of wordlines. Alternatively, SGS can be subdivided to provide subblocks. In such a configuration, whereas SGS is shown to apply to multiple SGD lines, there could be multiple SGS lines to a single SGD line. SRC represents a common source.

Channel 250 represents a vertical channel of the 3D array. The channel refers to a vertical stack of bitcells that can be charged through a channel connector. In one example, the channels couple to the bitline. It will be understood that there can be spatial dependencies in the stable Vt state of a channel. For example, the flow of charge carriers in the channel can be different at the different ends of the channels. Thus, blocks with specific wordlines may show worse degradation than others. The operation of controller 240 to mitigate read disturb due to stable Vt in the channel can be set by thresholds and operation that mitigates the most sensitive of the wordlines.

Each label, WL[0], WL[1], SGD[0], and so forth, indicates a select signal provided by control logic of decode logic 224, or a select signal provided by control logic of sense/output logic 226. In one example, decode logic 224 includes selection logic to select each of the signal lines illustrated. In one example, sense/output logic 226 enables the sensing of the contents of bitcells of 3D array 222, for either a read operation or to write a value back to the array. The output can be for a read operation to send data back to host 210. A write operation would include writing to a buffer to apply the values to the array.

It will be understood that a signal line in 3D array 222 is a wire or trace or other conductor that provides charge from a driver to the various elements or components. A driver circuit decode logic 224 provides the charge to charge up each signal line to the desired voltage for the desired operation. Each signal line can have an associated voltage level associated with certain operations. For example, each wordline can have a select voltage and a deselect voltage to indicate, respectively, wordlines that are selected for an operation and wordlines that are not selected for an operation.

In 3D array 222, it will be understood that the length of the wordlines can be substantial. In one example, the number of tiers of wordlines is on the order of tens or dozens of wordlines (e.g., N=28, 32, 36, 70, or more). In one example, the number of subblocks is on the order of ones or tens (e.g., M=8, 76, or more). Typically, the number of bitlines in 3D array 222 will be on the order of hundreds to thousands (e.g., P=2K). Thus, in one example, each bitline is relatively short compared to the length of the wordlines.

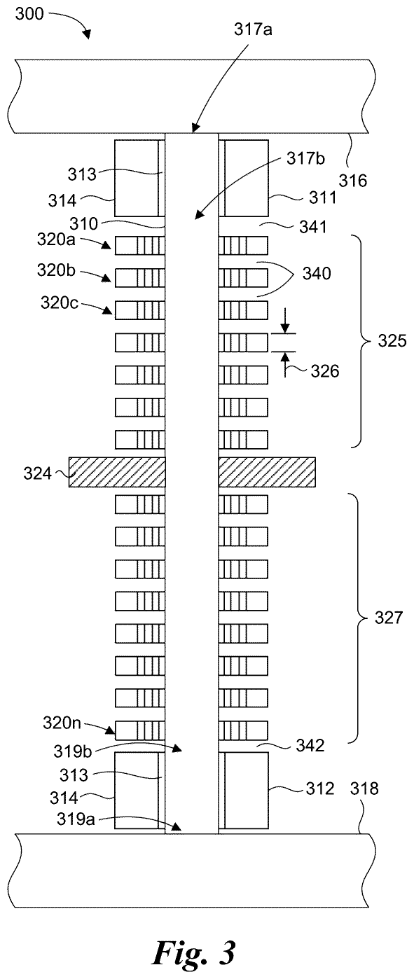

FIG. 3 shows an abstracted representation of a portion of a solid-state memory component 300, according to one example. In general, the portion of the solid-state memory component includes a memory pillar 310 and memory cells 320a-n (i.e., strings 325 and 327 of memory cells, which are two physical strings comprising one electrical string) located adjacent to the memory pillar 310. Strings 325 and 327 are located in respective decks separated by inter-deck 324. Memory pillar 310 may also be referred to as a “memory hole” in some embodiments. Any suitable number of memory cells can be included. The memory pillar 310 can act as a channel region for the memory cells 320a-n, which can be coupled in series. For example, during operation of one or more of the memory cells 320a-n of the string, a channel can be formed in the memory pillar 310. The memory pillar 310 and the string of memory cells 320a-n can be oriented vertically, such as in a three-dimensional memory array. For example, memory cell 320a is located at a vertical level (e.g., near the top of the memory array) that is above a vertical level (e.g., near the bottom of the memory array) at which memory cell 320n is located. Generally, memory cells 320a-n can have any suitable structure. A simplified memory cell structure is provided for context and by way of an example. Therefore, it should be recognized that suitable memory cell structures can vary from the memory cell structure shown in FIG. 3.

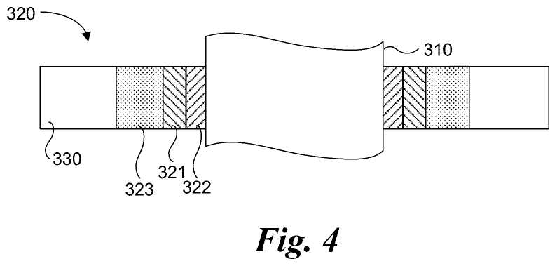

Each memory cell 320a-n in this example can have a charge-storage structure (e.g., that may be a conductive floating gate, a dielectric charge trap, etc.). For example, as shown in FIG. 4, which illustrates a cross-section side view, memory pillar 310 and a representative memory cell 320, the memory cell 320 can have a charge-storage structure 321. Each memory cell 320a-n can also have a tunnel dielectric interposed between its charge-storage structure and the channel in memory pillar 310. For example, the memory cell 320 can have a gate dielectric 313 interposed between the charge-storage structure 321 and the memory pillar 310. In addition, each memory cell 320a-n can have a control gate (e.g., as a portion of or coupled to access lines, such as word lines). For example, the memory cell 320 can include a control gate 330. Each memory cell can have one or more dielectric materials or dielectric layers interposed between its charge-storage structure and the control gate. For example, the memory cell 320 can include dielectric layer 323 interposed between the charge-storage structure 321 and the control gate 330 referred elsewhere in the text as inter-poly dielectric (IPD).

Each memory cell 320 may be a non-volatile memory cell and may have a charge-storage structure 321, such as a floating gate that may be a semiconductor (e.g., polysilicon), a charge trap layer that may be a dielectric film, etc. Non-limiting examples of dielectrics that are suitable for charge traps include nitrides, high-dielectric constant (high-K) dielectrics, such as alumina (Al₂O₃) having a K of about 10, with embedded conductive particles (e.g., nano-dots), such as embedded metal particles or embedded nano-crystals (e.g., silicon, germanium, or metal crystals), a silicon rich dielectric, or SiON/Si₃N₄. Embodiments of floating-gate and charge trap cells are described and illustrated below.

With further reference to FIG. 3, a dielectric 340 (also called an isolation layer) may be interposed between successively adjacent memory cells 320a-n in strings 325 and 327. For example, a dielectric 340 may be interposed between at least the charge-storage structure 321, the dielectric 323, and the control gates 330 of successively adjacent memory cells 320a-n. A dielectric 341 may be interposed between an end (e.g., between memory cell 320a) of strings 325, 327 and the select gate 311, and a dielectric 342 may be interposed between an opposite end (e.g., between memory cell 320n) of strings 325, 327 and the select gate 312, as shown in FIG. 4.

In some embodiments, where the charge-storage structure 321 is a charge trap, the tunnel dielectric 322, the charge-storage structure 321, and the dielectric 323 can form a continuous structure that can be shared by (e.g., that may be common to) two or more of the memory cells 320a-n. For example, such a structure can be shared by or common to all of the memory cells 320a-n.

Each of the memory cells 320a-n can have a thickness (e.g., a channel length) 326. For example, the memory cells 320a-n can have the same channel length regardless of where in strings 325, 327 the memory cells are located. In some embodiments, at least one channel length of a memory cell can be different from another channel length of another memory cell.

Each memory cell 320a-n of strings 325, 327 can be coupled in series with and can be between a select gate (e.g., a drain select gate) 311 adjacent to (e.g., in contact with) the pillar 310 and a select gate (e.g., a source select gate) 312 adjacent to (e.g., in contact with) the pillar 310. For a functional memory pillar, the pillar 310 is electrically coupled to a data line (e.g., a bit line 316), indicated at 317a and 317b. Thus, the select gate 311 can selectively couple strings 325, 327 to the data line (e.g., the bit line 316). In addition, for a functional memory pillar, the pillar 310 is electrically coupled to a source line 318, indicated at 319a and 319b. Thus, the select gate 312 can selectively couple strings 325, 327 to the source line 318. For example, the select gate 311 can be coupled in series with memory cell 320a, and the select gate 312 can be coupled in series with memory cell 320n. The select gates 311 and 312 can each include a gate dielectric 313 adjacent to (e.g., in contact with) pillar 310 and a control gate 314 adjacent to (e.g., in contact with) a corresponding gate dielectric 313.

FIG. 5 shows a circuit 500 that represents a portion of a vertical channel in a 3D memory structure, such as a 3D NAND array. Circuit 500 is not necessarily to scale and illustrates non-limiting example of features rather than providing an exact representation of features. Also, the shape of some of the cell structures are simplified for illustrative purposes.

Circuit 500 depicts two memory cells, cell 510 and cell 520 and three isolation layers 502, 504, and 506 (which may also be called separation layers). Although circuit 500 is not necessarily to scale, the isolation layers between the cells are generally thinner than the cells themselves. The cells illustrate one example of a memory cell structure, with semiconductor indicated as storage node 512 and storage node 522, respectively. Storage node 512 is separated from control gate poly by one or more IPD (inter-poly dielectric) layers 514. The conductor layer poly is a layer of conductor to control access to the storage node. The conductor layer poly for storage node 512 is represented as control gate 516. Likewise, storage node 522 is separated from conductor layer poly by one or more IPD layers 524, represented as control gate 526. The number of IPD layer and the structure of those layers is not important for circuit 500, as long as the storage node is electrically isolated from the conductor layer.

In one example, circuit 500 includes channel conductor 530 with a dielectric fill 532. 3D NAND typically uses polycrystalline (poly) material for channel 530, such as but not limited to polycrystalline silicon (also referred to as polysilicon). In one example, channel 530 may be p-type or n-type doped poly.

FIGS. 3 and 4 illustrate examples of ideal structures in which memory holes/pillars have perfectly straight sidewalls (i.e., constant diameter) and the thicknesses of dielectric layers remain the same from the top to the bottom of the memory holes/pillars. The aspect ratios (height to width or hole depth to hole diameter) are reduced in FIG. 3 for illustrative purposes and clarity—the aspect ratio in actual devices is greater, such as shown in some of the following Figures.

Generally, it is not possible or practical to form memory holes with high aspect ratios that have perfectly straight sidewalls. Rather, the memory holes have a slight amount of taper, with the diameter at the top of the memory hole being slightly greater than the diameter at the bottom. The memory holes are also not perfectly vertical due to process limitations. However, for illustrative purposes the structures shown in the schematic drawings below illustrate idealized structures.

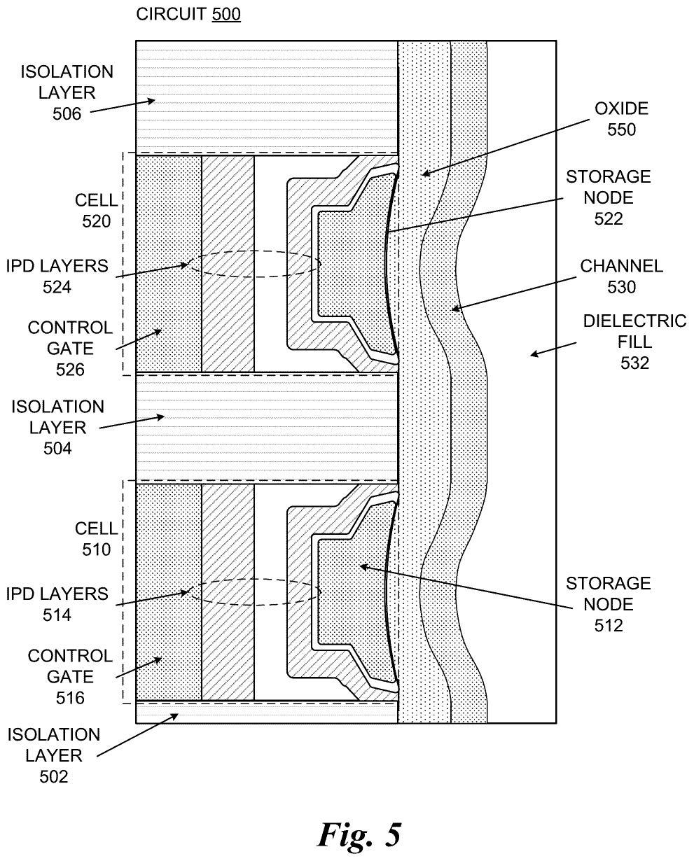

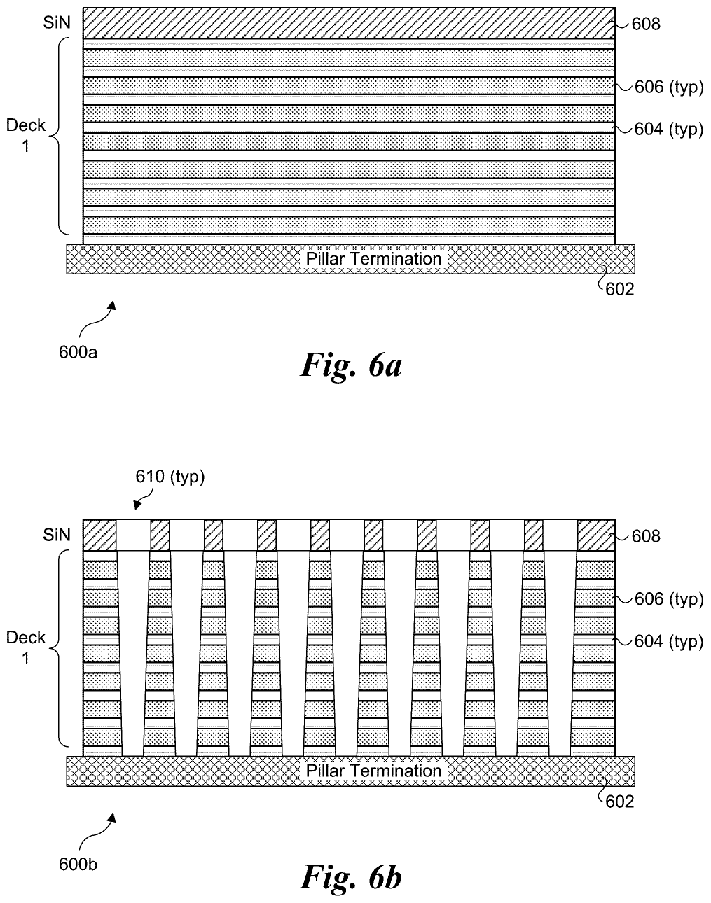

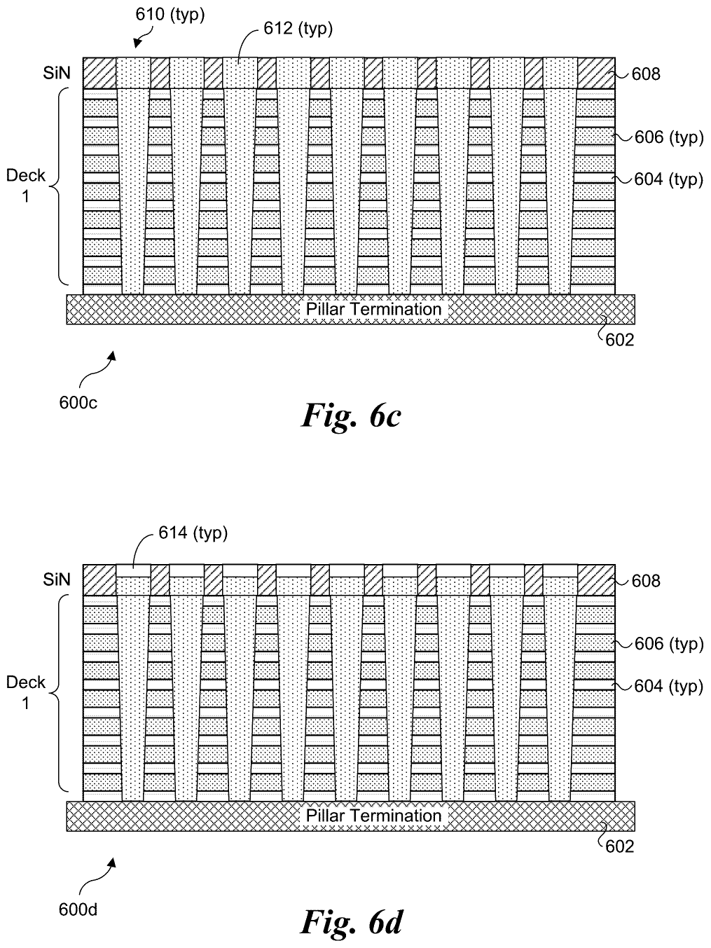

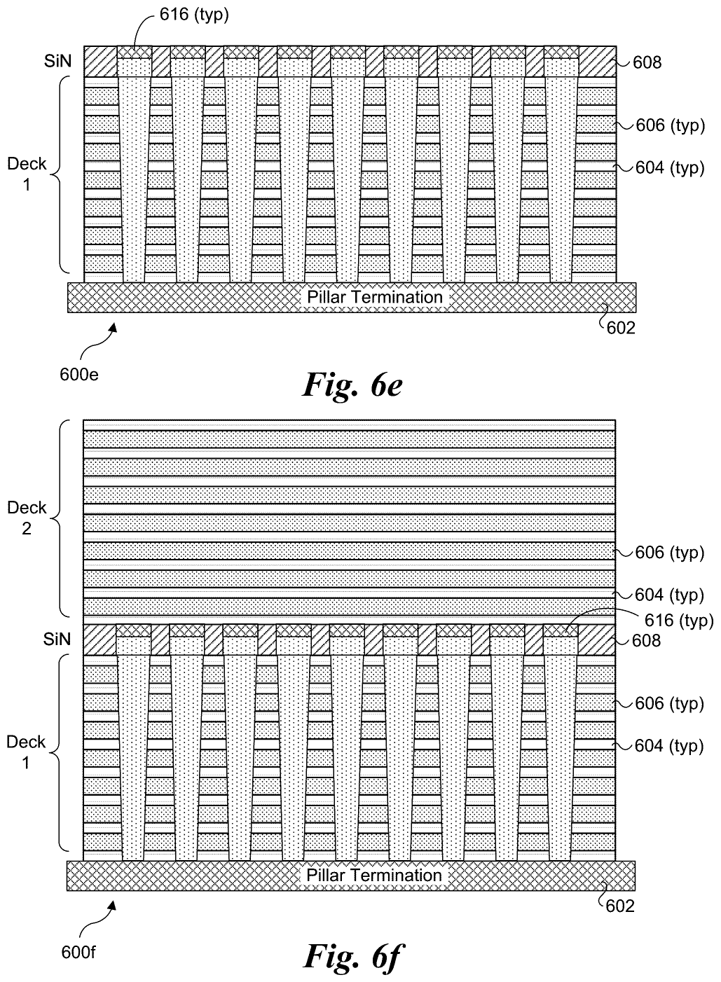

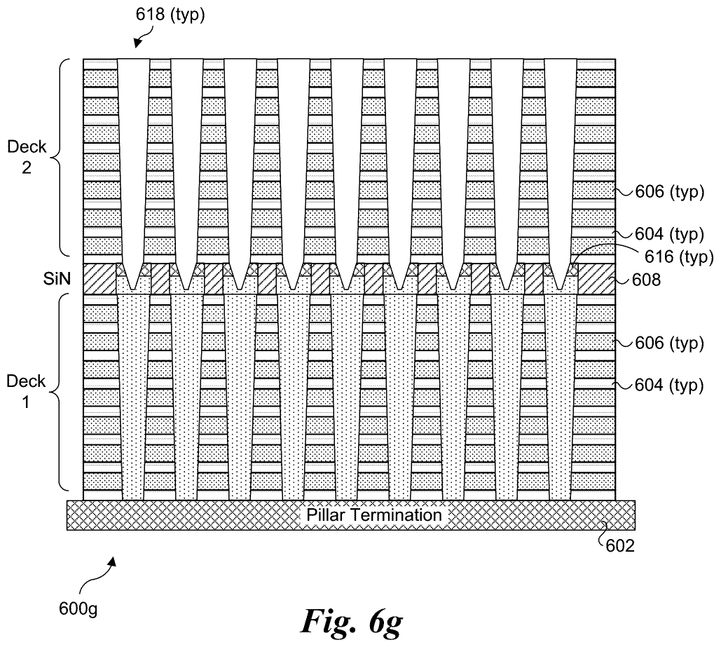

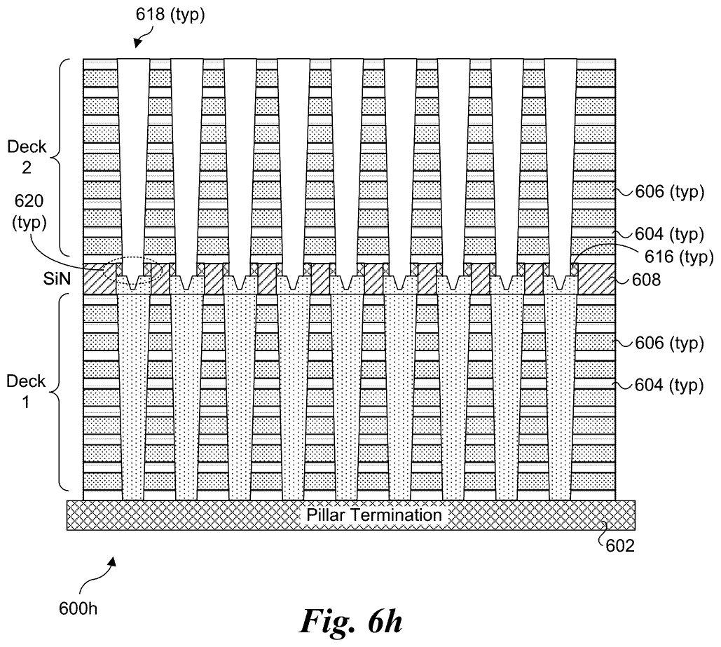

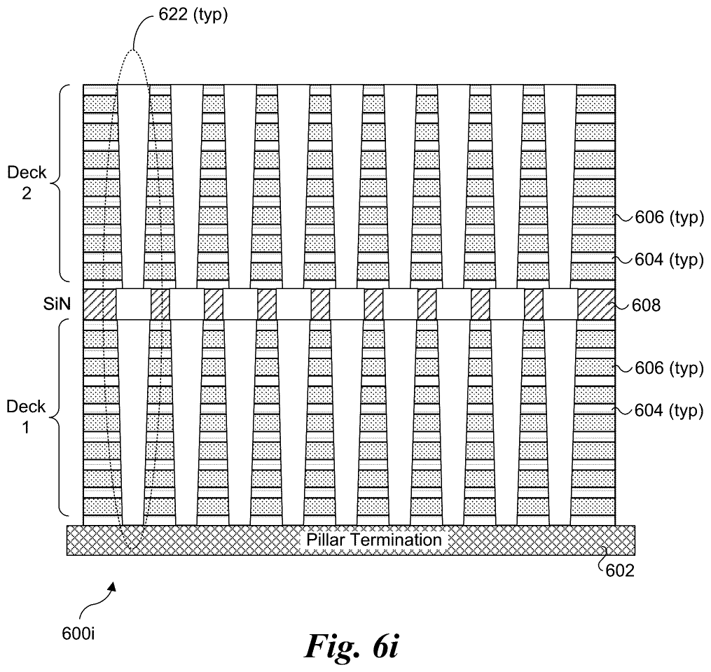

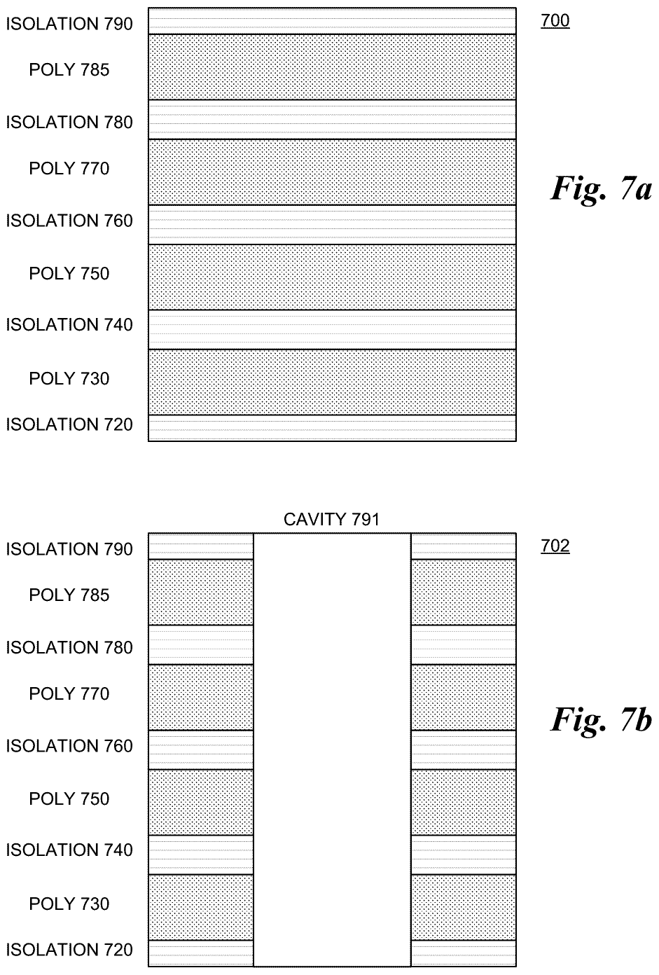

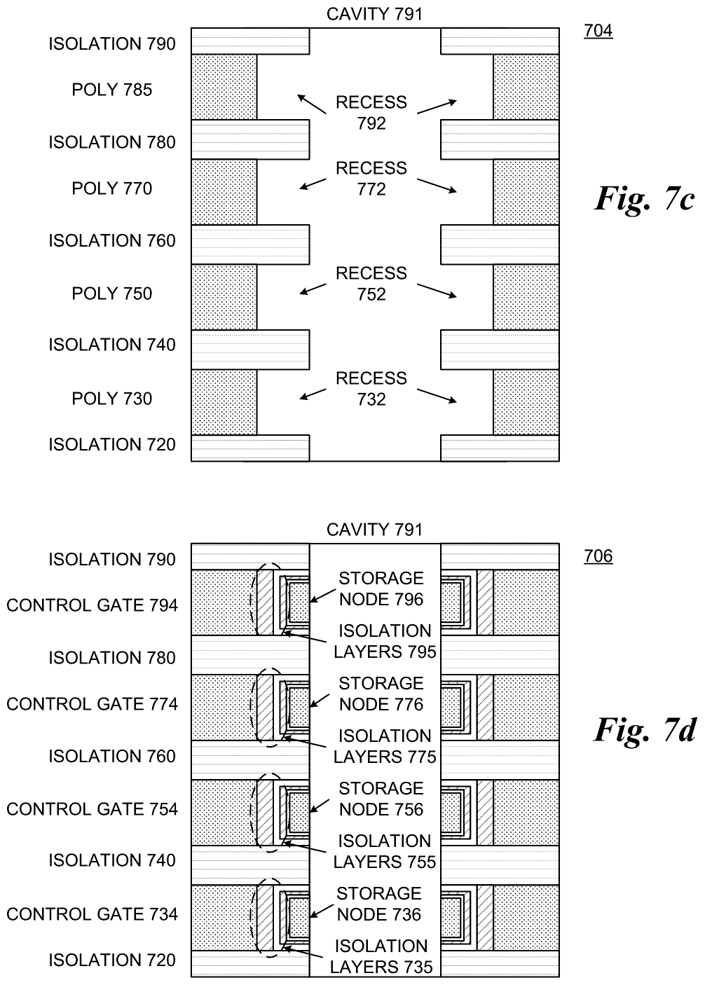

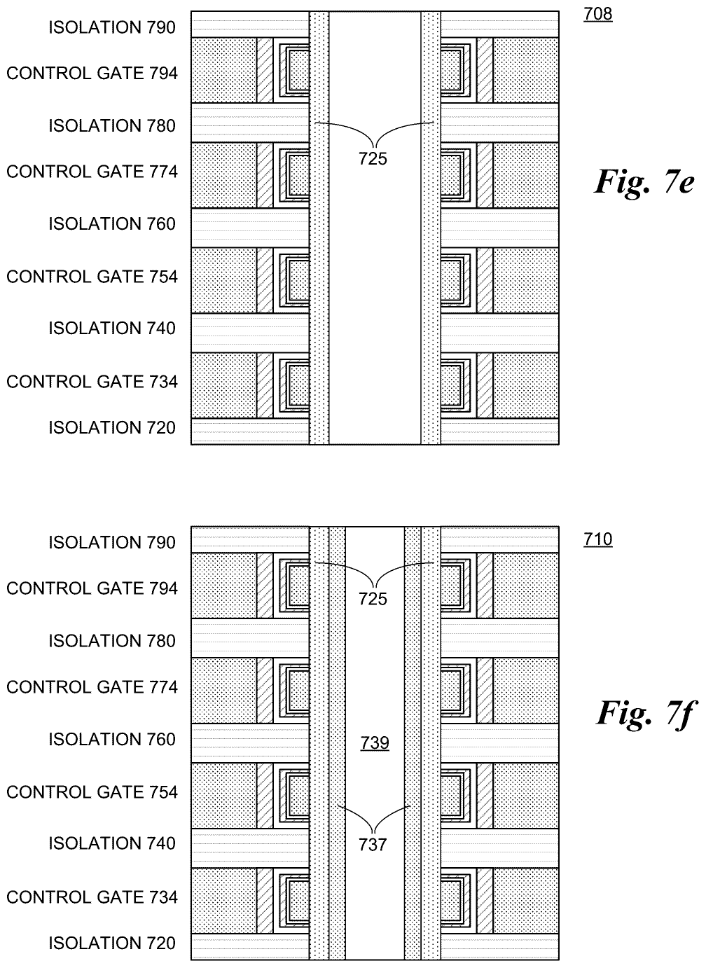

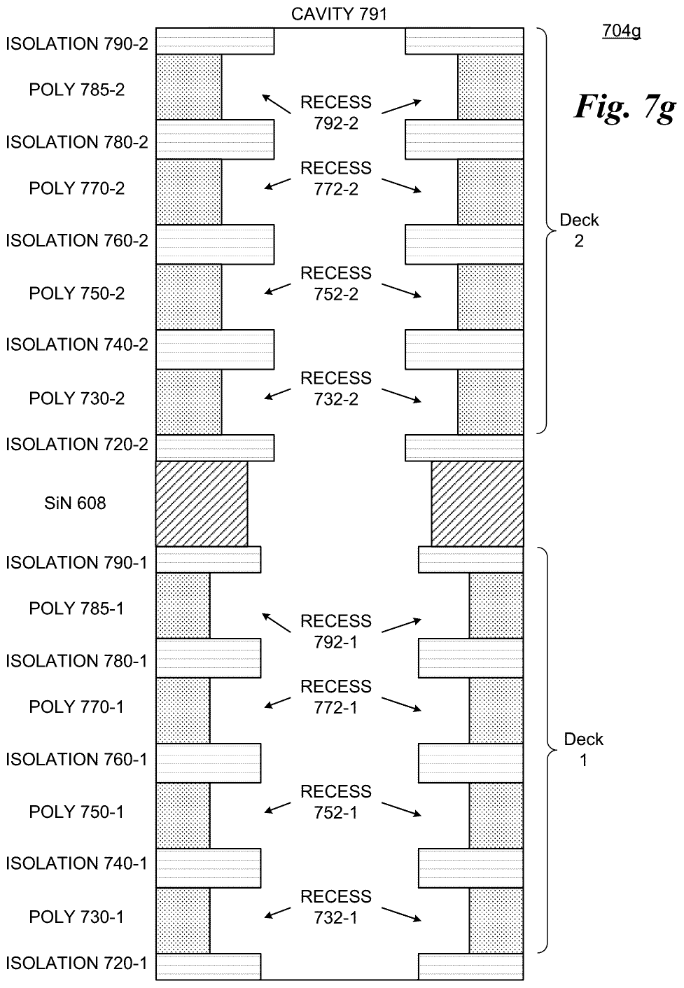

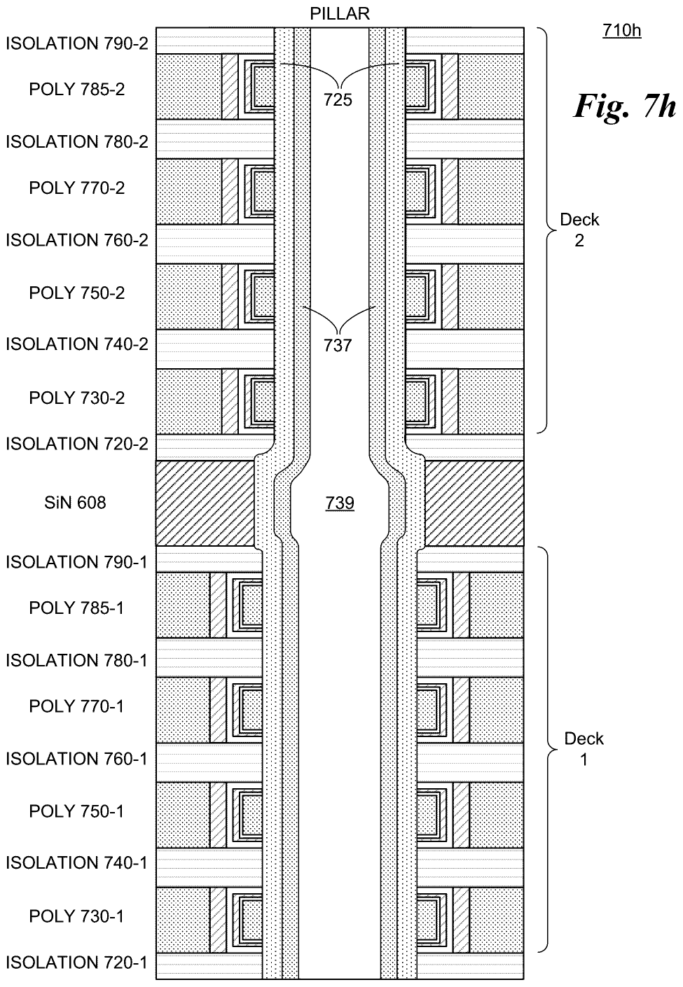

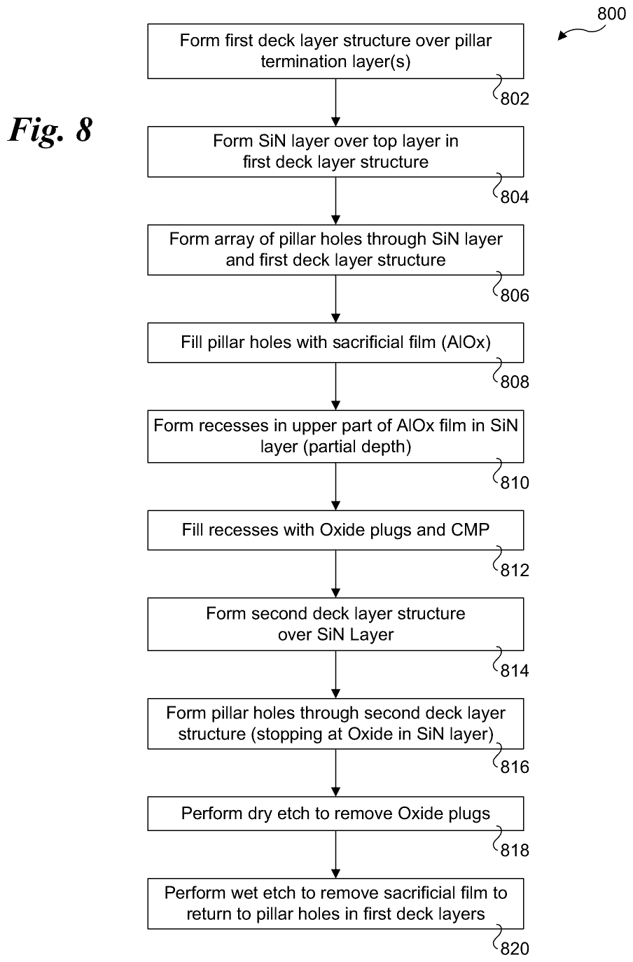

Processes for forming/fabricating semiconductor structures used in 3D NAND memory devices are shown in FIGS. 6a-6i, 7a-7g, and flowchart 800 of FIG. 8. As shown in a circuit state 600a in FIG. 6a and block 802 of flowchart 800, layers for a first deck are formed over a pillar termination layer(s) 602. The deck structure is formed of alternating isolation layers 604 and conductor (e.g., polysilicon) layers 606. A SiN layer 608 is formed over the top isolation layer, as depicted in block 804, with the resulting circuit state 600b shown in FIG. 6b. In one embodiment, SiN layer 608 is deposited using low-pressure chemical vapor deposition (LPCVP).

Moving to circuit state 600b in FIG. 6b, in block 806 an array of pillar holes 610 are formed through SiN layer 608 and the first deck layer structure. This is followed in block 808 by filling pillar holes 610 with a sacrificial film 612. In one embodiment, the sacrificial film is AlOx. The resulting semiconductor 600c is shown in FIG. 6c.

In block 810, recesses 614 are formed in the upper part of the AlOx fill in SiN layer 608 (partial depth), as shown in circuit state 600d in FIG. 6d. In block 812, the recesses are filled with an oxide plug 616, and chemical mechanical planarization (CMP) is applied, as shown in circuit state 600e in FIG. 6e. In one embodiment, the oxide plug comprises silicon oxide which is deposited using Tetraethyl orthosilicate (TEOS), which has a chemical formula SiC₈H₂₀O₄.

In block 814 a layered structure for a second deck is formed over SiN layer 608, as illustrated in circuit state 600f in FIG. 6f. As before, the second deck comprises alternating isolation layers 604 and conductor layers 606. An array of pillar holes 618 are formed in the second deck structure in block 816, stopping at the top of the oxide plugs 616 in SiN layer 608, as shown in circuit state 600g in FIG. 6g. The arrays of pillar holes 618 are (substantially) aligned with the array of pillar holes 610. For simplicity, the alignment shown in FIG. 6g-6i is perfect; as those skilled in the art will recognize, the alignment in actual 3D NAND devices may have a small level of misalignment.

Moving to circuit state 600h in FIG. 6h, in block 818 a dry etch operation is performed to remove the oxide plug 616, which (re)forms recesses 620. In block 820 a wet etch is performed to remove the sacrificial film to return the pillar holes in the first deck layers. The result of this operation leads to circuit state 600i in FIG. 6i. As shown, in this state pillar holes 622, which pass through the layered structures of both decks and the SiN inter-deck layer, are formed.

FIGS. 7a-7h are diagrammatic representations of a cross-section of stages of processing of a 3D memory structure, according to one embodiment. For purposes of example, FIGS. 7a-7h illustrate the processing to create a vertical channel and memory cell structures. The circuit states illustrated in FIGS. 7a-7h can apply to any example 3D memory structure, such as but not limited to circuit 500. The processing is illustrated only for a few layers of a 3D array. The processing will be understood to apply to other layers of the 3D array. The drawings are for purposes of discussion and are not necessarily to scale.

FIG. 7a illustrates circuit state 700, with layers of a 3D array being formed in a vertical stack. Circuit state 700 illustrates a portion of an entire vertical stack or vertically stacked layers of a storage array, where the substrate or wafer on which the circuit is formed is not shown. Other layers regarding selectors are also not shown. The stack can have dozens of layers of conductor and isolation layers.

Poly 730 represents a layer of conductor for a memory cell. Isolation layer 720 represents an electrical isolation layer between the conductor of poly 730 and layers below it (not shown). Circuit state 700 also shows poly 750, poly 770, and poly 785, which are conductor layers, and isolation 740, isolation 760, isolation 780, and isolation 790, alternating between the conductor layers. In one example, the conductor layers are layers of highly-doped polysilicon. In one example, the isolation layers are dielectric layers (e.g., Silicon Oxide). In one example, the isolation layers can be or include a nitride material.

FIG. 7b illustrates circuit state 702, in which the processing etches or removes a portion of the layers. The resulting etched isolation layer is represented as cavity 791. Cavity 791 represents a vertical cavity or vertical opening through the layers of conductor and isolation. For example, cavity 791 can be formed through an etch operation that forms holes in the 3D array structure. The etch can be performed in stages to achieve a vertical channel cut into the 3D array, recognizing the sidewalls of the channel will not be perfectly vertical due to process limitations. Cavity 791 is analogous to and may also be referred to the aforementioned pillar holes or memory holes.

FIG. 7c illustrates circuit state 704, in which the processing removes more material from the poly layers. The recesses created are illustrated as recess 732 for layer poly 730, recess 752 for layer poly 750, recess 772 for layer poly 770, and recess 792 to poly 785. The recesses are formed from cavity 791 into the poly layers and between the isolation layers. The depth of the recess can be controlled by a selective etch that etches the poly conductor and not the isolation material. The recess extends away from a center of cavity 791 and will thus extend away from the vertical channel to be formed. The recess can extend away from the center of cavity 791 toward respective control gates of the memory cells, or the control gates that control access to the storage nodes. The depth of the recesses depends on the structure of the storage node to be formed for the memory cells. Circuit state 704 illustrates recesses on both sides of cavity 791. It will be understood that cavity 791 is a three-dimensional structure, such as a vertical cylinder or circular column, whereas the view only illustrates a two-dimensional cutaway view.

FIG. 7d illustrates circuit state 706, in which the processing forms material in the exposed areas for memory cell storage. Storage node 736 represents a storage region for layer poly 730, which is identified in circuit state 706 as control gate 734. The poly layer is the control gate for storage node 736, to control access to the storage element. Isolation layers 735 represent one or more layers of isolation material to isolate the conductor of control gate 734 from the conductor of storage node 736. Storage node 756 represents a storage region for layer poly 750, which is identified as control gate 754. The poly layer is the control gate for storage node 756, to control access to the storage element. Isolation layers 755 represent one or more layers of isolation material to isolate the conductor of control gate 754 from the conductor of storage node 756. Storage node 776 represents a storage region for layer poly 770, which is identified as control gate 774. The poly layer is the control gate for storage node 776, to control access to the storage element. Isolation layers 775 represent one or more layers of isolation material to isolate the conductor of control gate 774 from the conductor of storage node 776. Storage node 796 represents a storage region for layer poly 785, which is identified as control gate 794. The poly layer is the control gate for storage node 796, to control access to the storage element. Isolation layers 795 represent one or more layers of isolation material to isolate the conductor of control gate 794 from the conductor of storage node 796. It will be understood that the various storage nodes will be formed in parallel. The formation of the storage nodes can include multiple processing operations that occur in series. The structure of the storage nodes is not necessarily exactly as shown. In one example, the storage nodes represent floating gates. In another example, the storage nodes represent charge trap layer. Models of floating gate cells and charge trap cells showing further details of the internal structure of the memory cells are presented below.

After the storage node is formed, a dielectric film may be deposited or grown out of storage node which forms the tunnel dielectric film 725 as shown in circuit state 708 in FIG. 7e. For example, tunnel dielectric film 725 may comprise a tunnel oxide. When used in the floating-gate structure of circuit 500 in FIG. 5, tunnel dielectric film 725 corresponds to oxide 550.

Subsequently, a channel conductor is formed over tunnel dielectric film 725, as shown in circuit state 710 in FIG. 7f. The channel conductor is represented as channel 737. In one example, channel 737 is a lightly doped (1e17/cm³-5e17/cm³) polysilicon material such as n-type (electron carrier majority) or p-type (hole carrier majority) channel. The remaining portion of the pillar holes may be filled with a dielectric fill 739.

Under one embodiment, recesses 732, 752, 772, and 792 shown in FIG. 7c are formed for each deck separately. For example, etching to form these recesses in the first deck may be performed between blocks 806 and 808 in flowchart 800, in one embodiment. Optionally, a set of recesses 732, 752, 772, and 792 are formed in both the first and second decks using the same etching process. This is schematically illustrated in circuit state 704g in FIG. 7g, where a “−1” or “−2” has been appended to the isolation layers, poly layers, and recesses shown in FIG. 7c for each of deck 1 and deck 2, which are separated by SiN layer 608 that is part of the inter-deck structure. Thus, with reference to circuit state 600i in FIG. 6i, the etching processes to form the recesses would occur after this circuit state has been fabricated.

FIG. 7h shows an example of a circuit state 710h comprising a super-deck structure including a pillar having a channel 737 that is used for memory cells in both the first and second decks. As shown, after the floating-gate memory cells are formed, tunnel dielectric film 725 is formed on the sidewalls of the pillar cavity (memory hole), followed by forming channel 737. It will be recognized that the number of memory tiers in each of the first and second decks is multiple times what is shown in FIG. 7h.

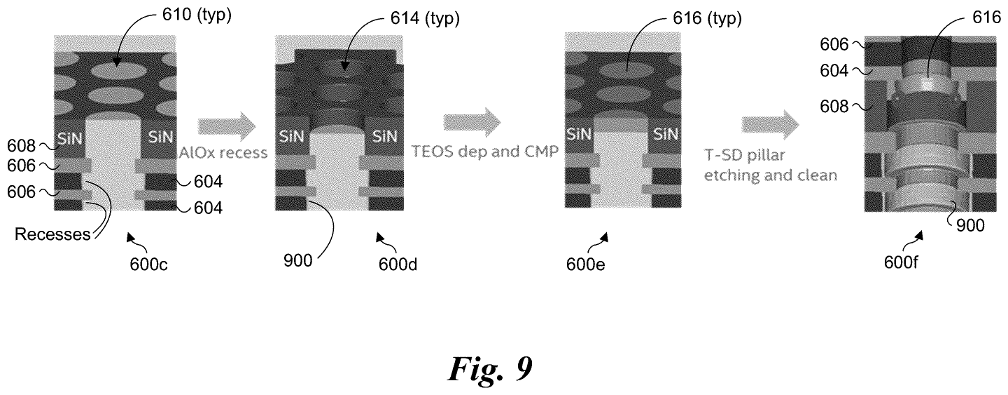

FIG. 9 shows further details of selected processes discussed and illustrated above. In this version of semiconductor structure 600c, etching to form recesses has been performed before filling the pillar holes with sacrificial film (AlOx) 612. Under circuit state 600d, recesses 614 are formed in AlOx 612 in the manner discussed above for block 810 in flowchart 800. Next, TEOS deposition and CMP is performed (block 812) to create oxide plugs 616, as shown in circuit state 600e. T-SD pillar etching and cleaning is then performed to obtain circuit state 600f.

FIG. 9 also shows use of an optional barrier layer 900 that is used to protect against a control gate poly-AlOx chemical reaction. The optional barrier layer may comprise a thin film of oxide that is deposited on the sidewall of the pillar holes prior to depositing AlOx 612. The optional barrier layer is also removed during the wet etch and cleaning process.

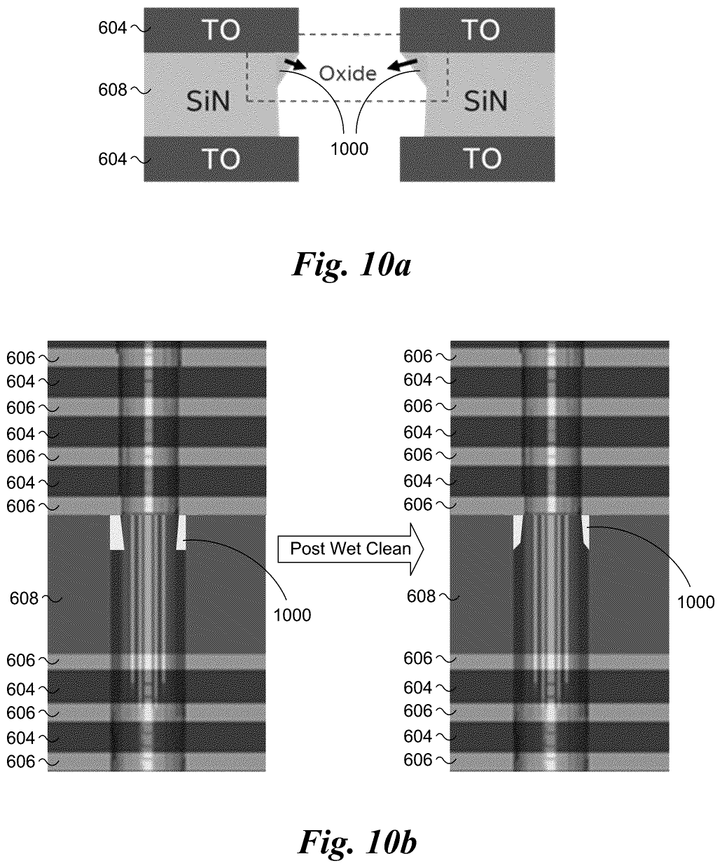

FIGS. 10a and 10b shows further details of a reduction in oxide residual that results using the 3D memory fabrication processes utilizing the hybrid plug described herein. As illustrated, there is a small amount of oxide residual 1000 in the upper corners of where the SiN layer 608 meets the upper isolation layer 604 (noting the amount of oxide residual is exaggerated in FIG. 10a for clarity).

FIG. 10b shows a model of the semiconductor structure fabrication process, illustrating oxide residual 1000 before and after the wet cleaning (wet etch step) is performed. In practice, using the fabrication process disclosed herein will result in oxide residue in the upper corners being eliminated or substantially eliminated. This amount of oxide residual is substantially reduced when compared with semiconductor structures produced using a current fabrication process, such as shown in FIG. 13, wherein the circled parts depict “hiding-side” areas of residual oxide.

FIG. 11 shows further details of the hybrid plug 1100. This shows the circuit state 600h (FIG. 6h) after the processing operations in blocks 816 and 820. As illustrated, the dry etch operation (block 820) will not completely remove all of oxide plug 616 and will remove a small portion of AlOx film 612.

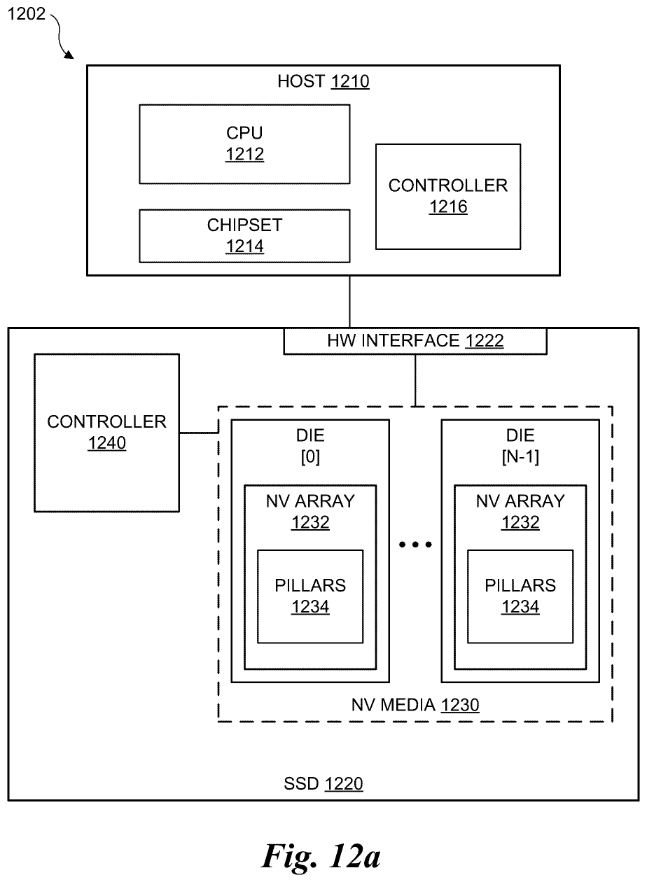

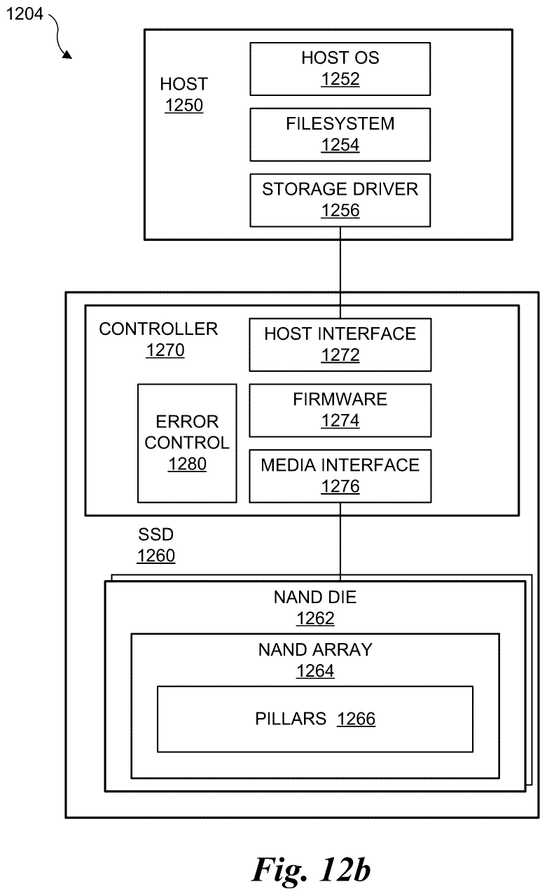

FIG. 12a is a block diagram of an example of a system with a hardware view of a solid-state drive (SSD) with a nonvolatile array having a vertical channel with conductive structures. System 1202 represents components of a nonvolatile storage system that could implement nonvolatile media having a vertical string with low resistance structures in accordance with any example described, such as in system 100, or in accordance with the processing sequences described above.

System 1202 includes SSD 1220 coupled with host 1210. Host 1210 represents a host hardware platform that connects to SSD 1220. Host 1210 includes CPU (central processing unit) 1212 or other processor as a host processor or host processor device. CPU 1212 represents any host processor that generates requests to access data stored on SSD 1220, either to read the data or to write data to the storage. Such a processor can include a single or multicore processor, a primary processor for a computing device, a graphics processor, a peripheral processor, or a supplemental or auxiliary processor, or a combination. CPU 1212 can execute a host OS and other applications to cause the operation of system 1202.

Host 1210 includes chipset 1214, which represents hardware components that can be included in connecting between CPU 1212 and SSD 1220. For example, chipset 1214 can include interconnect circuits and logic to enable access to SSD 1220. Thus, host 1210 can include a hardware platform drive interconnect to couple SSD 1220 to host 1210. Host 1210 includes hardware to interconnect to the SSD. Likewise, SSD 1220 includes corresponding hardware to interconnect to host 1210.

Host 1210 includes controller 1216, which represents a storage controller or memory controller on the host side to control access to SSD 1220. In one example, controller 1216 is included in chipset 1214. In one example, controller 1216 is included in CPU 1212. Controller 1216 can be referred to as an NV memory controller to enable host 1210 to schedule and organize commands to SSD 1220 to read and write data.

SSD 1220 represents a solid-state drive or other storage system or module that includes nonvolatile (NV) media 1230 to store data. SSD 1220 includes HW (hardware) interface 1222, which represents hardware components to interface with host 1210. For example, HW interface 1222 can interface with one or more buses to implement a high-speed interface standard such as NVMe (nonvolatile memory express) or PCIe (peripheral component interconnect express).

In one example, SSD 1220 includes NV media 1230 as the primary storage for SSD 1220. In one example, NV media 1230 is or includes a block addressable memory technology, such as NAND (not AND) or NOR (not OR). In one example, NV media 1230 can include a nonvolatile media that can be block addressable or byte addressable, which stores data based on a resistive state of the memory cell, or a phase of the memory cell. For example, NV media 1230 can be or include a 3D XPOINT™ (3DXP) memory or a storage array based on chalcogenide phase change material (e.g., chalcogenide glass). In one example, the NV media can be or include multi-threshold level NAND flash memory, NOR flash memory, single or multi-level phase change memory (PCM) or phase change memory with a switch (PCMS), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

In one example, NV media 1230 is implemented as multiple dies, illustrated as N dies, Die[0:{N-1}]. N can be any number of devices, and is often a binary number. SSD 1220 includes controller 1240 to control access to NV media 1230. Controller 1240 represents hardware and control logic within SSD 1220 to execute control over the media. Controller 1240 is internal to the nonvolatile storage device or module, and is separate from controller 1216 of host 1210.

The NV dies of NV media 1230 include NV array 1232, which represents a 3D array of storage cells based on the NV media. NV array 1232 includes arrays of pillars fabricated using the techniques disclosed herein and labeled as pillars 1234. Pillars 1234 include one or more layers of dielectric material(s), such as but not limited to tunnel oxides, in accordance with one of more of the embodiments described and illustrated herein.

FIG. 12b is a block diagram of an example of a logical view of system with a solid-state drive (SSD) with a nonvolatile array having a vertical channel with conductive structures. System 1204 provides one example of a system in accordance with system 1202 of FIG. 12a. System 1204 illustrates the logical layers of the host and SSD of a hardware platform in accordance with system 1202. System 1204 can represent software and firmware components of an example of system 1202, as well as physical components. In one example, host 1250 provides one example of host 1210. In one example, SSD 1260 provides one example of SSD 1220.

In one example, host 1250 includes host OS 1252, which represents a host operating system or software platform for the host. Host OS 1252 can include a platform on which applications, services, agents, and/or other software executes, and is executed by a processor. Filesystem 1254 represents control logic for controlling access to the NV media. Filesystem 1254 can manage what addresses or memory locations are used to store what data. There are numerous filesystems known, and filesystem 1254 can implement known filesystems or other proprietary systems. In one example, filesystem 1254 is part of host OS 1252.

Storage driver 1256 represents one or more system-level modules that control the hardware of host 1250. In one example, drivers 1256 include a software application to control the interface to SSD 1260, and thus control the hardware of SSD 1260. Storage driver 1256 can provide a communication interface between the host and the SSD.

Controller 1270 of SSD 1260 includes firmware 1274, which represents control software/firmware for the controller. In one example, controller 1270 includes host interface 1272, which represents an interface to host 1250. In one example, controller 1270 includes media interface 1276, which represents an interface to NAND die 1262. NAND die 1262 represents a specific example of NV media, and includes an associated NAND array 1264, which represents a 3D NAND array.

NAND array 1264 includes arrays of pillars fabricated using the techniques disclosed herein and labeled as pillars 1266. Pillars 1266 include one or more layers of dielectric material(s), such as but not limited to tunnel oxides.

Media interface 1276 represents control that is executed on hardware of controller 1270. It will be understood that controller 1270 includes hardware to interface with host 1250, which can be considered to be controlled by host interface software/firmware 1274. Likewise, it will be understood that controller 1270 includes hardware to interface with NAND die 1262. In one example, code for host interface 1272 can be part of firmware 1274. In one example, code for media interface 1276 can be part of firmware 1274.

In one example, controller 1270 includes error control 1280 to handle data errors in accessed data, and corner cases in terms of compliance with signaling and communication interfacing. Error control 1280 can include implementations in hardware or firmware, or a combination of hardware and software. Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A process for fabricating a three-dimensional (3D) memory device, comprising:
forming a first deck layered structure comprising alternating isolation and conductor layers having a top isolation layer;
forming a Silicon Nitride (SiN) layer over the top isolation layer;
forming an array of pillar holes vertically passing through the SiN layer and layers in the first layered structure; and
filling an upper portion of the pillar holes with a hybrid plug comprising first and second oxides, wherein the first oxide is disposed above the second oxide and has a depth that is less than a thickness of the SiN layer.

2. The process of claim 1, wherein the hybrid plug is formed by:
filling the pillar holes with a sacrificial film comprising the second oxide;
etching an upper portion of the sacrificial film to form recesses in an upper portion of the SiN layer, the recesses have a depth less than the thickness of the SiN layer; and
depositing the first oxide in the recesses.

3. The process of claim 1, wherein the second oxide comprising an Aluminum Oxide (AlOx).

4. The process of claim 1, wherein the first oxide comprises a Silicon Oxide (SiOx).

5. The process of claim 1, further comprising:
forming a second deck layered structure comprising alternating isolation and conductor layers having a bottom isolation layer formed over the SiN layer; and
forming an array of pillar holes vertically passing through the second deck layered structure and stopping at the first oxide in respective hybrid plugs.

6. The process of claim 5, further comprising performing a dry etch to remove at least a portion of the first oxide.

7. The process of claim 6, further comprising performing a wet etch to remove at least a portion of the second oxide and to remove sacrificial film in the pillar holes in the first deck layered structure.

8. The process of claim 6, wherein the wet etch further removes at least a portion of the first oxide.

9. The process of claim 6, wherein the wet etch eliminates or substantially eliminates first oxide residual in recesses formed in the SiN layer.

10. The process of claim 1, wherein the 3D memory device comprises a 3D NAND memory device.

11. A three-dimensional (3D) NAND memory structure comprising:
first and second decks, each comprising a plurality of tiers of memory cells and composed of conductive layers interposed between isolation layers, each tier of memory cells comprising a two-dimensional (2D) array of floating gate memory cells formed in a conductive layer;
a silicon nitride (SiN) layer disposed between a top isolation layer in the first deck and a bottom isolation layer in the second deck; and
a plurality of vertical pillars, passing through the memory cells in the conductive layers and isolation layers in the first and second decks and passing through the SiN layer,
wherein a diameter of a portion of a vertical pillar passing through the SiN layer is greater than a diameter of a portion of the vertical pillar passing through the bottom isolation layer in the second deck.

12. The 3D NAND memory structure of claim 11, wherein the diameter of the portion of a vertical pillar passing through the SiN layer is greater than a diameter of a portion of the vertical pillar passing through the top isolation layer in the first deck.

13. The 3D NAND memory structure of claim 11, wherein an oxide residual in an upper corner of a portion of a vertical pillar passing through the SiN layer is eliminated or substantially eliminated.

14. The 3D NAND memory structure of claim 11, wherein the vertical pillars have a profile from top to bottom comprising:
a first portion passing through layers in the second deck having a slight amount of taper, wherein a diameter at a top isolation layer in the second deck is greater than a diameter in the bottom isolation layer of the second deck;
a second portion passing through the SiN layer; and
a third portion passing through layers in the first deck having a slight amount of taper, wherein a diameter at the top isolation layer in the first deck is greater than a diameter in a bottom isolation layer of the first deck.

15. The 3D NAND memory structure of claim 11, wherein the vertical pillars have an outer sidewall comprising tunnel dielectric film over which a channel conductor is formed.

16. An apparatus, comprising
one or more three-dimensional (3D) NAND memory structures including,
first and second decks, each comprising a plurality of tiers of memory cells and composed of conductive layers interposed between isolation layers, each tier of memory cells comprising a two-dimensional (2D) array of floating gate memory cells formed in a conductive layer;
a silicon nitride (SiN) layer disposed between a top isolation layer in the first deck and a bottom isolation layer in the second deck;
a plurality of vertical pillars, passing through the memory cells in the conductive layers and isolation layers in the first and second decks and passing through the SiN layer, wherein a diameter of a portion of a vertical pillar passing through the SiN layer is greater than a diameter of a portion of the vertical pillar passing through the bottom isolation layer in the second deck;
a controller, operative coupled to each of the 3D NAND memory devices; and
a host interface.

17. The apparatus of claim 16, where the one or more memory structures comprise 3D NAND dies.

18. The apparatus of claim 16, wherein an oxide residual in an upper corner of a portion of the vertical pillar passing through the SiN layer is eliminated or substantially eliminated.

19. The apparatus of claim 16, wherein the vertical pillars have a profile from top to bottom comprising:
a first portion passing through layers in the second deck having a slight amount of taper, wherein a diameter at a top isolation layer in the second deck is greater than a diameter in the bottom isolation layer of the second deck;
a second portion passing through the SiN layer; and
a third portion passing through layers in the first deck having a slight amount of taper, wherein a diameter at the top isolation layer in the first deck is greater than a diameter in a bottom isolation layer of the first deck.

20. That apparatus of claim 16, wherein the apparatus comprises a solid-state drive (SSD).
